(19) United States
(12) Patent Application Publication
(10) Pub. No.: US 2008/0211002 A1
(43) Pub. Date: Sep. 4, 2008

(54) SEMICONDUCTOR DEVICE AND METHOD OF MANUFACTURING THE SAME

(75) Inventors: Yoshitaka NAKAMURA, Tokyo (JP); Takashi ARAO, Tokyo (JP); Jiro MIYAHARA, Tokyo (JP); Shigeo ISHIKAWA, Tokyo (JP); Koji URABE, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/963,255

(22) Filed: Dec. 21, 2007

(30) Foreign Application Priority Data
Dec. 26, 2006 (JP) 2006-349319

(51) Int. Cl. H01L 27/108; H01L 21/02

(52) U.S. Cl. 257/303; 438/387; 257/E27.084; 257/E21.011

(57) ABSTRACT

This semiconductor device includes: a first cylinder interlayer insulating film; a second cylinder interlayer insulating film; a cylinder hole including a first cylinder hole and a second cylinder hole communicating with the first cylinder hole; and a capacitor including a lower electrode and an upper electrode. The first cylinder interlayer insulating film has an etching rate for etchant, which is two to six times as high as an etching rate for the second cylinder interlayer insulating film, a hole diameter of the first cylinder hole is larger than that of the second cylinder hole, and the hole diameter of the second cylinder hole near an interface between the first cylinder interlayer insulating film and the second cylinder interlayer insulating film increases as the second cylinder hole approaches the interface.

Priority is claimed on Japanese Patent Application No. 2006-349319, filed Dec. 26, 2006, the contents of which are incorporated herein by reference.

### BACKGROUND OF THE INVENTION

1. Field of the Invention

The present invention relates to a semiconductor device and a method of manufacturing the same, and more particularly, to a semiconductor device with a DRAM-typed capacitor and a method of manufacturing the same.

2. Description of the Related Art

Memory cells, such as DRAM (Dynamic Random Access Memory) and the like, each including select transistors and capacitors, suffer from reduction in charge storage of capacitors as the memory cells grow smaller and smaller with advance of micro-machining technology. A COB (Capacitor Over Bitline) structure and a STC (Stacked Trench Capacitor) structure have been employed to overcome such a reduction problem. In these structures, an area of a capacitor electrode is increased by forming a capacitor over a bit line to increase bottom area (projection area) and height of the capacitor.

In general, a dry etching technology is being used to form a cylinder hole in a cylinder interlayer insulating layer on which a capacitor is formed. However, since the cylinder hole has its lower hole diameter smaller than its upper hole diameter, charge storage capacitance of the lower hole grows smaller.

To overcome this problem, two interlayer insulating layers having different wet-etching rates are used as cylinder interlayer insulating layers, as disclosed in Non-Patent Document: S. G. Kim et al., Extended Abstract of the 2004 International Conference on Solid State Devices and Materials, Tokyo, 2004, pp 714-715. As disclosed in this document, a cylinder hole formed in the two interlayer insulating layers including an upper layer and a lower layer having wet-etching rate higher than the upper layer is enlarged by wet-etching in such a manner that its lower hole diameter is increased over its upper hole diameter, thereby increasing charge storage capacitance in the lower hole.

However, the technology of this document has a problem of increase of leak current when the capacitor is formed in the cylinder hole. In particular, an MIM (metal/capacitive insulating layer/metal) type capacitor using metal such as a titanium nitride (TiN) layer for a lower electrode and an upper electrode has a problem of significant increase of leak current.

In consideration of such circumstances, an object of the present invention is to provide a semiconductor device including a cylinder interlayer insulating layer formed of two interlayer insulating films in which charge storage capacitance is increased in a lower cylinder hole by making a diameter of the lower cylinder hole larger than a diameter of an upper cylinder hole, and a capacitor having low leak current.

Another object of the present invention is that it provides a method of manufacturing a semiconductor device including a cylinder interlayer insulating layer formed of two interlayer insulating films in which a diameter of a lower cylinder hole is larger than a diameter of an upper cylinder hole, and a capacitor having low leak current.

### SUMMARY OF THE INVENTION

To solve the above problems, the present inventors have carefully reviewed and found that the problem of increase of leak current is caused by alien substances, which may be produced in a lower electrode forming process, left in a steep step occurring at an interface between two interlayer insulating films in a cylinder hole in a process of enlarging a hole diameter of the cylinder hole.

In addition, the present inventors have carefully reviewed a relationship between a step in the cylinder hole and increase of leak current and have found that the problem of increase of leak current in an MIM type capacitor is caused by a method of removing a resist provided to protect an etch back of a lower electrode of the MIM type capacitor when the lower electrode is formed.

That is, in a MIS (metal/capacitive insulating film/semiconductor) type capacitor using semiconductor such as silicon in a lower electrode, typically, a resist provided to protect an etch back of the lower electrode is removed using acid peeling liquid having high resist removal effect.

On the contrary, in the MIM type capacitor, since metal such as titanium nitride is used for the lower electrode, acid peeling liquid can not be used to remove the resist provided to protect the etch back of the lower electrode. Accordingly, in the MIM type capacitor, the resist provided to protect the etch back of the lower electrode is removed using a dry ashing method.

In removing the resist using the acid peeling liquid, since the resist is isotropically removed, alien substances are hardly left even when a step occurs in the cylinder hole. However, in removing the resist using the dry ashing method, if a step occurs in the cylinder hole, there may occur a portion at which ashing particles such as ions or radicals having directionality are difficult to arrive, alien substance are apt to be left. Accordingly, the MIM type capacitor has a significant problem of increase of leak current as compared to the MIS type capacitor.

The present inventors has discovered that such a problem of increase of leak current can be solved by providing a semiconductor device without any step occurring in a cylinder hole whose lower portion is larger in its hole diameter than its upper portion and have made the present invention based on such a discovery.

According to an aspect of the present invention, there is provided a semiconductor device including: a first cylinder interlayer insulating film; a second cylinder interlayer insulating film formed on the first cylinder interlayer insulating film; a cylinder hole including a first cylinder hole formed in the first cylinder interlayer insulating film and a second cylinder hole formed in the second cylinder interlayer insulating film and communicating with the first cylinder hole; and a capacitor including a lower electrode formed to cover bottom and lateral sides of the cylinder hole and an upper electrode formed on a surface of the lower electrode via a capacitive insulating film. The first cylinder interlayer insulating film has an etching rate for etchant used for wet-etching of the first cylinder interlayer insulating film and the second cylinder interlayer insulating film which is two to six times as high as an etching rate for the second cylinder interlayer insulating film; a hole diameter of the first cylinder hole is larger than a hole diameter of the second cylinder hole; and the hole diameter of the second cylinder hole near an interface between the first cylinder interlayer insulating film and the second cylinder interlayer insulating film increases as the second cylinder hole approaches the interface.

In the semiconductor device according to the aspect of the present invention, since the hole diameter of the first cylinder hole is formed to be larger than the hole diameter of the second cylinder hole and the hole diameter of the second cylinder hole near the interface between the first cylinder interlayer insulating film and the second cylinder interlayer insulating film increases as the second cylinder hole approaches the interface, a resist provided to protect an etch back of the lower electrode of the capacitor when the lower electrode is formed can be effectively removed using either acid peeling liquid or a dry ashing method, thereby preventing alien substances, which may be produced in the lower electrode forming process, from being left.

Accordingly, the semiconductor device of the present invention is excellent in that charge storage capacitance in the first cylinder hole constituting the lower portion of the cylinder hole is increased and the capacitor has low leak current.

Preferably, the first cylinder interlayer insulating film is formed of an USG film.

Preferably, the second cylinder interlayer insulating film is formed of a PE-TEOS film.

Preferably, the etchant is a mixture solution of NH₃ and H₂O₂.

Preferably, the lower electrode is formed of a titanium nitride film.

Preferably, the capacitive insulating film is one of an aluminum oxide film, a hafnium oxide film, a zirconium oxide film and a tantalum oxide film, or a laminate of at least two of the films.

Preferably, the lower electrode is electrically connected to MISFET for memory cell selection provided in bottom of the capacitor.

Preferably, an angle θ between the interface and an extension direction of an inner wall of the second cylinder hole contacting the interface falls within a range of 60° to 85°.

According to another aspect of the present invention, there is provided a method of manufacturing a semiconductor device having a capacitor including a lower electrode formed to cover bottom and lateral sides of a cylinder hole and an upper electrode formed on a surface of the lower electrode via a capacitive insulating film, a process of forming the capacitor including the steps of: sequentially forming a first cylinder interlayer insulating film and a second cylinder interlayer insulating film; forming the cylinder hole including a first cylinder hole formed in the first cylinder interlayer insulating film and a second cylinder hole formed in the second cylinder interlayer insulating film and communicating with the first cylinder hole, wet etching the cylinder hole using etchant allowing an etching rate of the first cylinder interlayer insulating film to be two to six times as high as an etching rate of the second cylinder interlayer insulating film such that a hole diameter of the first cylinder hole is larger than hole diameter of the second cylinder hole and the hole diameter of the second cylinder hole, near an interface between the first cylinder interlayer insulating film and the second cylinder interlayer insulating film increases as the second cylinder hole approaches the interface; forming the lower electrode on the bottom and lateral sides of the cylinder hole; and forming the upper electrode on the surface of the lower electrode via the capacitive insulating film.

According to the method of manufacturing the semiconductor device, since the cylinder hole is wet-etched using the etchant allowing the etching rate of the first cylinder interlayer insulating film to be two to six times as high as the etching rate of the second cylinder interlayer insulating film, the hole diameter of the first cylinder hole can be formed to be larger than the hole diameter of the second cylinder hole and the hole diameter of the second cylinder hole near the interface between the first cylinder interlayer insulating film and the second cylinder interlayer insulating film can increase as the second cylinder hole approaches the interface without any steep step occurring near the interface between the first cylinder hole and the second cylinder hole. Accordingly, a shape of the cylinder hole obtained in the etching process has little effect on resist removal when a resist provided to protect an etch back of the lower electrode of the capacitor when the lower electrode is formed is removed using either acid peeling liquid or a dry ashing method, thereby preventing alien substances, which may be produced in the lower electrode forming process, from being left.

Accordingly, the method of manufacturing the semiconductor device of the present invention can provide an excellent semiconductor device in which charge storage capacitance in the first cylinder hole constituting the lower portion of the cylinder hole is increased and the capacitor has low leak current.

Preferably, the first cylinder interlayer insulating film is formed of an USG film.

Preferably, the second cylinder interlayer insulating film is formed of a PE-TEOS (Plasma Enhanced chemical vapor deposition-TEOS) film.

Preferably, the etchant is a mixture solution of NH₃ and H₂O₂.

Preferably, the lower electrode is formed of a titanium nitride film.

Preferably, the capacitive insulating film is one of an aluminum oxide film, a hafnium oxide film, a zirconium oxide film and a tantalum oxide film, or a laminate of at least two of the films.

Preferably, the step of forming the lower electrode includes: forming a conductive film to be the lower electrode; forming a resist film on the conductive film and forming a protection resist film having a predetermined shape by selectively removing the resist film; forming the lower electrode by selectively removing the conductive film using the protection resist film; and removing the protection resist film using a dry ashing method.

As described above, the effects obtained in the present invention are as follows.

In the semiconductor device of the present invention, since the hole diameter of the first cylinder hole is formed to be larger than the hole diameter of the second cylinder hole and the hole diameter of the second cylinder hole near the interface between the first cylinder interlayer insulating film and the second cylinder interlayer insulating film increases as the second cylinder hole approaches the interface, the semiconductor device of the present invention is excellent in that charge storage capacitance in the first cylinder hole constituting the lower portion of the cylinder hole is increased and the capacitor has low leak current.

In addition, according to the method of manufacturing the semiconductor, since the cylinder hole is wet-etched using the etchant allowing the etching rate of the first cylinder interlayer insulating film to be two to six times as high as the etching rate of the second cylinder interlayer insulating film it is possible to realize a semiconductor device with high reliability in which charge storage capacitance in the first cylinder hole constituting the lower portion of the cylinder hole is increased and the capacitor has low leak current without any steep step occurring near the interface between the first cylinder hole and the second cylinder hole.

### BRIEF DESCRIPTION OF THE DRAWINGS

FIG. 1 is a cross-sectional view of a semiconductor memory device having an MIM type capacitor according to a first mode of the present invention.

FIG. 2 is an enlarged view of a capacitor in the semiconductor memory device.

FIG. 3 is a cross-sectional view of the semiconductor memory device for each step of a method of manufacturing the semiconductor memory device.

FIG. 4 is a cross-sectional view of the semiconductor memory device for each step of a method of manufacturing the semiconductor memory device.

FIG. 5 is a cross-sectional view of the semiconductor memory device for each step of a method of manufacturing the semiconductor memory device.

FIG. 6 is a cross-sectional view of the semiconductor memory device for each step of a method of manufacturing the semiconductor memory device.

FIG. 7 is a cross-sectional view of the semiconductor memory device for each step of a method of manufacturing the semiconductor memory device.

FIG. 8 is a cross-sectional view of the semiconductor memory device for each step of a method of manufacturing the semiconductor memory device.

FIG. 9 is a cross-sectional view of the semiconductor memory device for each step of a method of manufacturing the semiconductor memory device.

FIG. 10 is a cross-sectional view of the semiconductor memory device for each step of a method of manufacturing the semiconductor memory device.

FIG. 11 is a cross-sectional view of the semiconductor memory device for each step of a method of manufacturing the semiconductor memory device.

FIG. 12 is a cross-sectional view of the semiconductor memory device for each step of a method of manufacturing the semiconductor memory device.

FIG. 13 is a cross-sectional view of a sample wafer of Example 1.

FIG. 14 is a cross-sectional view of a sample wafer of Comparative Example 1.

FIGS. 15A and 15B are graphs showing an I-V characteristic of a sample wafer of Example 4.

FIGS. 16A and 16B are graphs showing an I-V characteristic of a sample wafer of Comparative Example 4.

### DETAILED DESCRIPTION OF THE INVENTION

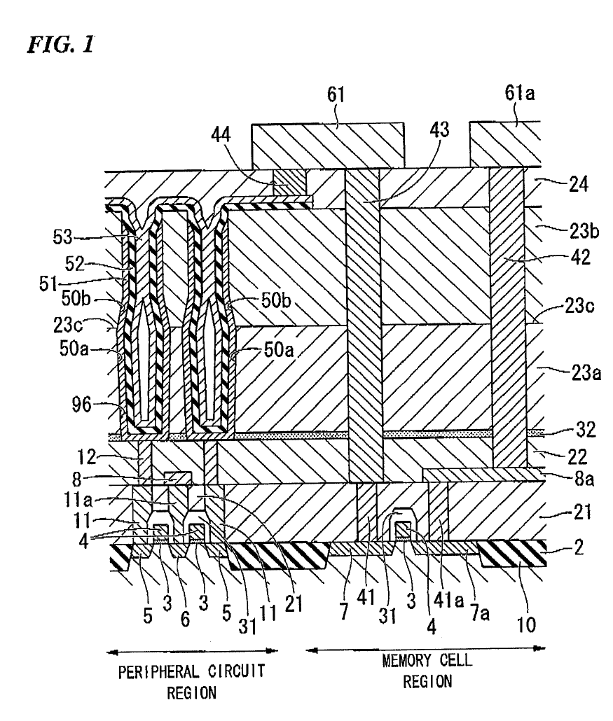

A semiconductor memory device having an MIM type capacitor and a method of manufacturing the same according to a first mode of the present invention will be described with reference to FIGS. 1 to 12.

### (1) Structures of a Semiconductor Memory Device and a Capacitor.

FIG. 1 is a cross-sectional view of a semiconductor memory device according to the first mode of the present invention. In a memory cell shown in FIG. 1, two select transistors (MISFETs for memory cell selection) are formed in an active region defined by partitioning a main surface of a silicon substrate 10 by an isolation insulating film 2. The select transistors each include a gate electrode 4 formed on the main surface of the silicon substrate 10 via a gate insulating film 3, and a pair of diffusion layer regions 5 and 6 as a source region and a drain region, with the diffusion layer region 6 shared between the select transistors. In addition, in the select transistors, a bit line 8 (tungsten film) formed on an interlayer insulating film 21 and an interlayer insulating film 31 and the diffusion layer region 6 of the pair of diffusion layer regions 5 and 6 are connected to a polysilicon plug 11a passing through the interlayer insulating film 21.

The bit line 8 is covered by an interlayer insulating film 22 (silicon oxide film) on which a capacitor is formed.

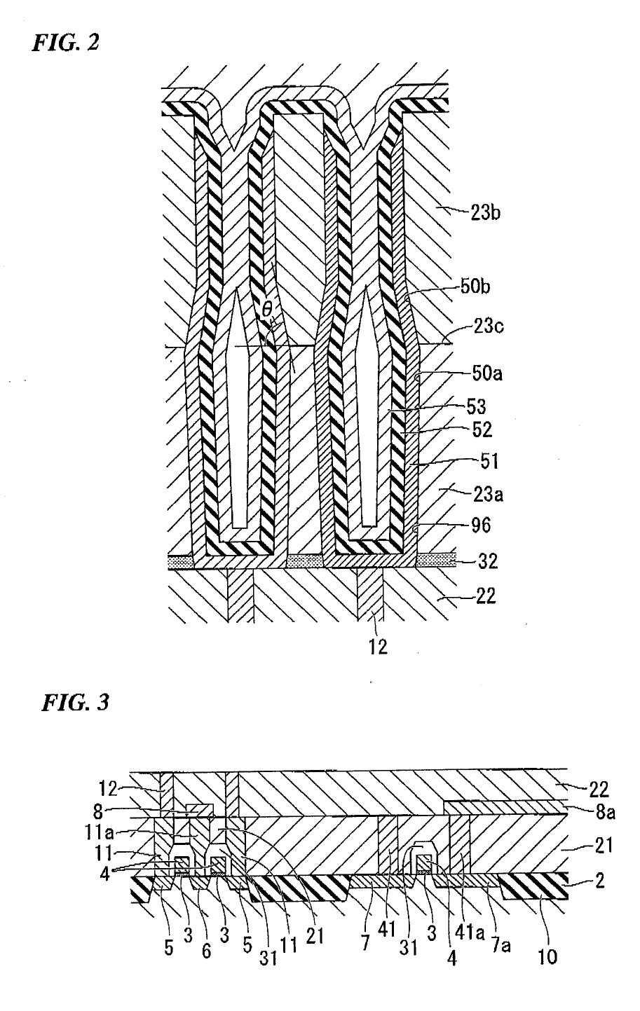

FIG. 2 is an enlarged view of the capacitor in the semiconductor memory device shown in FIG. 1. As shown in FIG. 2, the capacitor is formed in a cylinder hole 96 including a first cylinder hole 50a formed in a first cylinder interlayer insulating film 23a and a second cylinder hole 50b formed in a second cylinder interlayer insulating film 23b and communicating with the first cylinder hole 50a.

The first cylinder interlayer insulating film 23a is an USG (Undoped Silicate Glass) film. The second cylinder interlayer insulating film 23b is a PE-TEOS film. The first cylinder interlayer insulating film 23a has all etching rate for etchant used for wet-etching of the first cylinder interlayer insulating film 23a and second cylinder interlayer insulating film 23b, which is two to six times as high as an etching rate for the second cylinder interlayer insulating film 23b.

A lower electrode 51 is formed of a first titanium nitride film and has a cup shape to cover bottom and lateral sides of the cylinder hole 96. On a surface of the lower electrode 51, there formed an upper electrode 53 which is formed of a second titanium nitride film, via a capacitive insulating film 52 formed of an aluminum oxide film.

Although the capacitive insulating film 52 is formed of the aluminum oxide film as mentioned above, the capacitive insulating film 52 is not limited to the aluminum oxide film but may be formed of, for example, one of a habit oxide film, a zirconium oxide film and a tantalum oxide film, or one of two or more laminates such as a laminate of the aluminum oxide film and hafnium oxide film.

As shown in FIG. 2, a diameter of the first cylinder hole 50a is formed to be larger than a diameter of the second cylinder hole 50b. The diameter of the second cylinder hole 50b near an interface 23c between the first cylinder interlayer insulating film 23a and the second cylinder interlayer insulating film 23b increases as it approaches the interface 23c. Accordingly a hole diameter of the lower electrode 51 is formed to be larger in its lower portion than in its upper portion, with its maximum hole diameter at the interface 23c, and the cross section of the lower electrode 51 is smooth without any steep step.

In this mode of the present invention, as shown in FIG. 2, an angle θ between the interface 23c and an extension direction of an inner wall of the second cylinder hole 50b contacting the interface 23c falls within a range of 60° to 85°.

If the angle θ is less than the range, the inner wall of the second cylinder hole 50b contacting the interface 23c becomes a step in the cylinder hole 96 which may make it difficult to remove a resist film formed in a lower electrode form process which will be described later, and accordingly, the capacitor may disadvantageously have high leak current.

On the other hand, if the angle θ is more than the range, a difference between the hole diameter of the second cylinder hole 50a and the hole diameter of the second cylinder hole 50b is insufficient, which may result in insufficient charge storage capacitance in the first cylinder hole 50a.

In addition, as shown in FIG. 1, the lower electrode 51 is connected to the polysilicon plug 12 at the bottom of the lower electrode 51 passing through a silicon nitride film 32, and the polysilicon plug 12 is electrically connected to the diffusion layer region 5 of the transistor via a lower polysilicon plug 11.

In addition, a second layer wire 61 is formed on the upper electrode 53, with both electrically connected to each other by a metal plug 44 formed through an interlayer insulating film 24.

On the other hand, in a peripheral circuit region shown in FIG. 1, a transistor for peripheral circuit is formed in the active region defined by partitioning the main surface of the silicon substrate 10 by the isolation insulating film 2. The transistor for peripheral circuit includes a gate electrode 4 formed via the gate insulating film 3, and a pair of diffusion layer regions 7 and 7a as a source region and a drain region. The diffusion layer region 7 of the transistor is electrically connected to the second layer wire 61 via a metal plug 41 and a metal plug 43, and the diffusion layer region 7a is electrically connected to a first layer wire 8a via a metal plug 41a. The first layer wire 8a is electrically connected to a second layer wire 61a via a metal plug 42.

### (2) Method of Manufacturing a Semiconductor Memory Device and a Capacitor.

Next a method of manufacturing the semiconductor memory device shown in FIG. 1 will be described with reference to FIGS. 1 to 12.

First, the main surface of the silicon substrate 10 is partitioned by the isolation insulating film 2, and then, the gate insulating film 3, the gate electrode 4, the diffusion layer regions 5, 6, 7 and 7a, the interlayer insulating film 31, the polysilicon plug 11, the metal plugs 41 and 41a, the bit line 8 and the first layer wire 8a are formed. Subsequently, the interlayer insulating film 22 is formed on the bit line 8 and the first layer wire 8a, a contact hole passing through the interlayer insulating film 22 is filled with a polysilicon film, and the interlayer insulating film 22 is etched back to form the polysilicon plug 12 (FIG. 3).

Next, the silicon nitride 32 is formed. The silicon nitride 32 functions as an etching stopper film when a cylinder hole is formed later. Subsequently, the first cylinder interlayer insulating film 23a as an USG film and the second cylinder interlayer insulating film 23b as a PE-TEOS film are sequentially formed as cylinder interlayer insulating films (FIG. 4).

The first cylinder interlayer insulating film 23a is formed by a PECVD (Plasma-Enhanced CVD) method using monosilane (SiH₄) and nitrogen monoxide (N₂O), for example. The second cylinder interlayer insulating film 23b is formed by a PECVD method using TEOS (Si(OC₂H₅)₄) and oxygen (O₂), for example.

As described above, the first cylinder interlayer insulating film 23a has an etching rate for etchant used for wet-etching of the first cylinder interlayer insulating film 23a and second cylinder interlayer insulating film 23b, which is two to six times as high as an etching rate for the second cylinder interlayer insulating film 23b.

If the etching rate of the first cylinder interlayer insulating film 23a is less than the above range, a difference between the hole diameter of the second cylinder hole 50a and the hole diameter of the second cylinder hole 50b is insufficient, which may result in insufficient charge storage capacitance in the first cylinder hole 50a. On the other hand, if the etching rate of the first cylinder interlayer insulating film 23a is more than the above range, the inner wall of the second cylinder hole 50b contacting the interface 23c becomes a step in the cylinder hole 96 which may make it difficult to remove a resist film formed in a lower electrode forming process which will be described later.

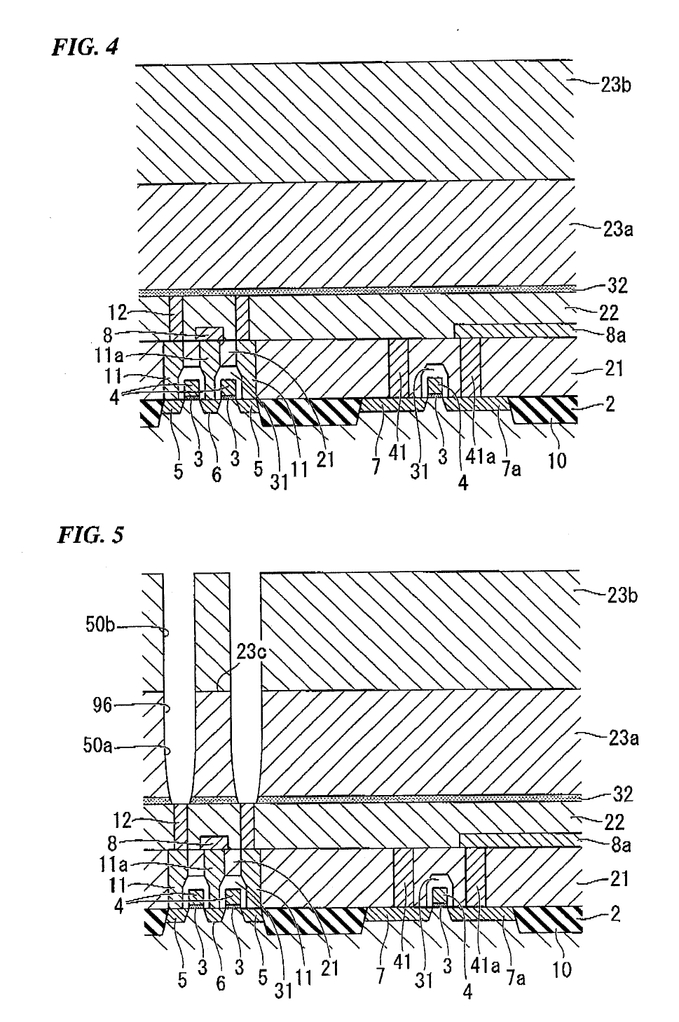

Next, the cylinder hole 96 passing through the first cylinder interlayer insulating film 23a, the second cylinder interlayer insulating film 23b and the silicon nitride film 32 is formed by a photolithography technique and an etching technique, and then a surface of the polysilicon plug 12 is exposed to the bottom of the cylinder hole 96 (FIG. 5). Accordingly, the cylinder hole 96 including the first cylinder hole 50a formed in the first cylinder interlayer insulating film 23a and the second cylinder hole 50b formed in the second cylinder interlayer insulating film 23b and communication with the first cylinder hole 50a is formed.

Next, wet etching treatment (etching process) is carried out to enlarge the cylinder hole 96. The wet etching treatment is carried out using etchant allowing the etching rate of the first cylinder interlayer insulating film 23a to be two to six times as high as the etch rate of the second cylinder interlayer insulating film 23b. Specifically, examples of the etchant may include a mixture solution of ammonia (NH₃) and hydrogen peroxide (H₂O₂), a diluted hydrogen fluoride (DHF) solution, a mixture solution of ammonium fluoride (NH₄F) and hydrogen fluoride (HF), a solution obtained by adding surfactant to these solutions, etc.

If the mixture solution of ammonia and hydrogen peroxide is used as the etchant, a ratio of ammonia to hydrogen peroxide (NH₃:H₂O₂) is preferably 10:1˜1:10, and the mixture solution is preferably one to 1000 times diluted with water (H₂O). If the ammonia portion is out of the ratio, the etching rate may be disadvantageously suddenly lowered.

If the diluted hydrogen fluoride (DHF) is used as the etchant, the content of hydrogen fluoride (HF) in DHF is preferably 0.0001 to 0.1 wt %. If the content of hydrogen fluoride (HF) in DHF is less than this range, the etching rate is disadvantageously suddenly lowered. If the content of hydrogen fluoride (HF) in DHF exceeds this range, the etching rate is disadvantageously uncontrollably increased.

Here, for example, when ammonia (NH₃) and hydrogen peroxide (H₂O₂) are mixed with a ratio of 1:1˜1:5 (NH₃:H₂O₂) and a mixture solution with dilution of water (H₂O) 20 times is used, the wet etching treatment may be carried out by dipping the first and second cylinder holes 50a and 50b into the mixture solution at 50 to 80° C. for one to five minutes. With this wet etching treatment, the 3˜60 nm diameter of the first cylinder holes 50a is increased and the 1˜20 nm diameter of the second cylinder holes 50b is increased.

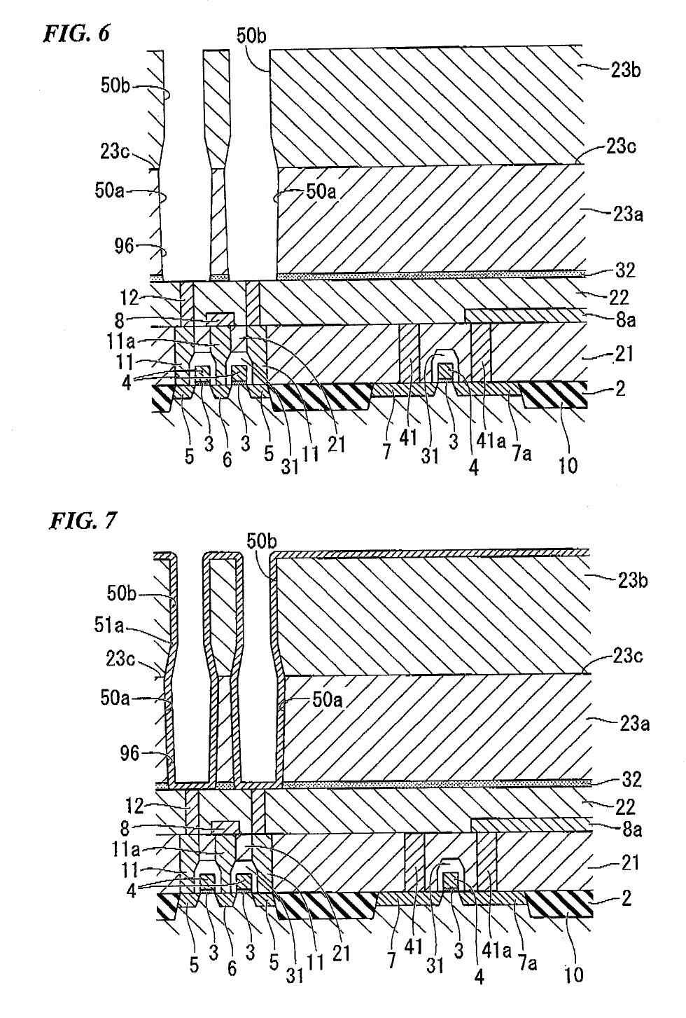

In the cylinder hole 96 obtained by the wet etching treatment, the hole diameter of the first cylinder hole 50a is larger than the hole diameter of the second cylinder hole 50b, and the hole diameter of the second cylinder hole 50b near the interface 23c between the first cylinder interlayer insulating film 23a and the second cylinder interlayer insulating film 23b becomes large as it approaches the interface 23c. Accordingly, the cylinder hole 96 has a smooth cross section without any steep step (FIG. 6).

Next, heat treatment is carried out to alleviate stress of the first and second interlayer insulating films 23a and 23b. Thereafter, the lower electrode 5 is formed is the bottom and lateral sides of the cylinder hole 96 (lower electrode forming process).

In the lower electrode forming process, first, a titanium nitride film 51a (conducive film) having thickness of 15 nm which will be the lower electrode 51 is grown by a CVD method (FIG. 7).

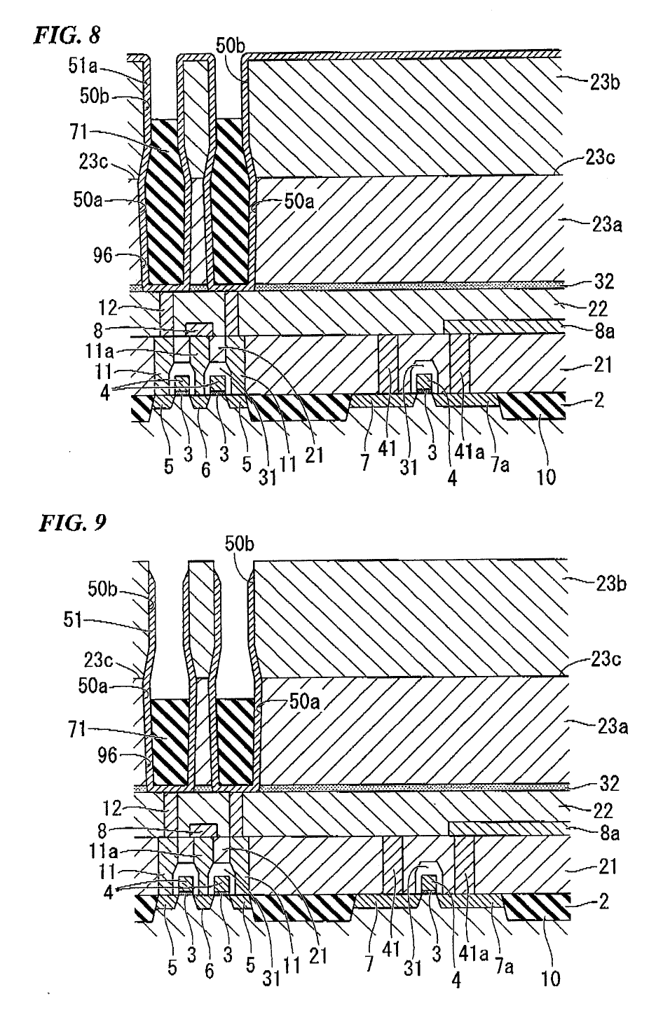

Next, a resist film is formed on the titanium nitride film 51a, and then the resist film is selectively removed to form a photoresist film 71 (passivation resist film) having a predetermined shape (FIG. 8).

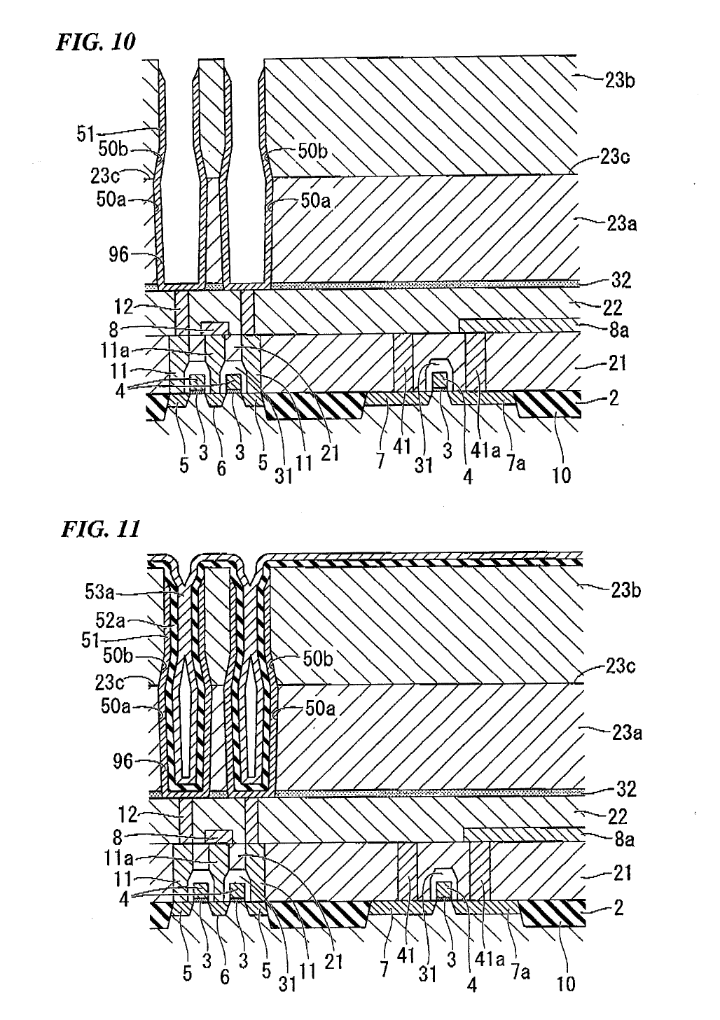

Subsequently, the photoresist film 71 is used to selectively etch back the titanium nitride film 51a to form the lower electrode of a cup type (FIG. 9). Thereafter, the photoresist film 71 is removed by a dry-ashing method using vapor (H₂O), oxygen (O₂) and argon (Ar) gas (resist removal process). Thereafter, ashing residue is dissolved away by organic stripping liquid (FIG. 10).

Next the aluminum oxide film 52a as the capacitive insulating film 52 is formed on a surface of the lower electrode 51 by an ALD (Atomic Layer Deposition) method. Subsequently, the second titanium nitride film 53a as the upper electrode 53 is formed on the capacitive insulating film 52 by a CVD method (FIG. 11).

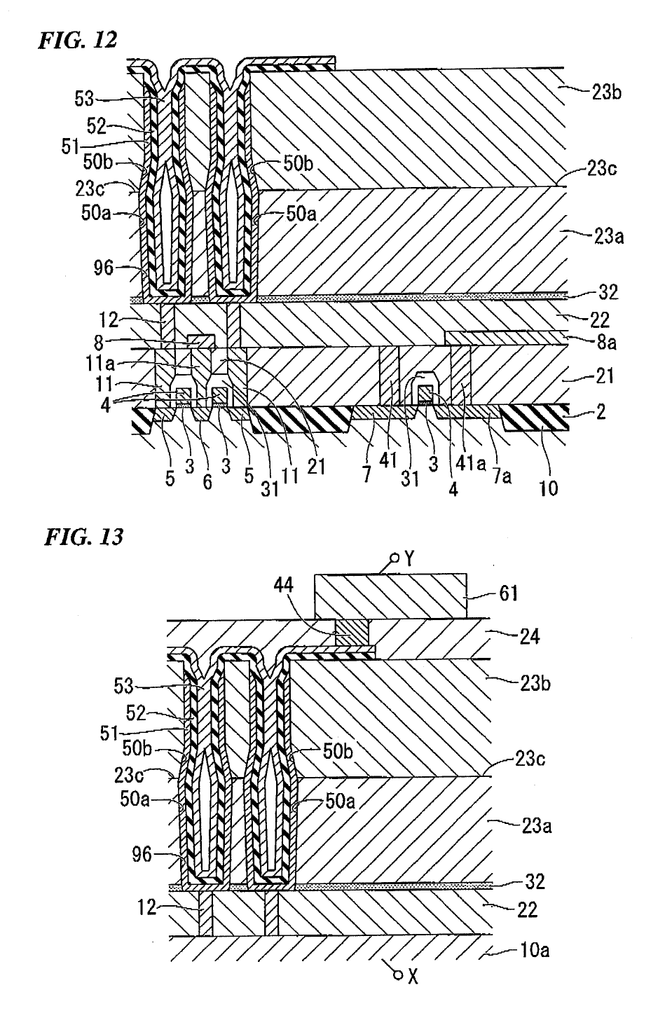

Thereafter, the second titanium nitride film 53a and the aluminum oxide film 52a are machined into the shape of upper electrode 53 by a photolithography technique and a dry etching technique to obtain the cylinder-shaped capacitor (FIG. 12).

Next, the interlayer insulating film 24 as a silicon oxide film is formed, the interlayer insulating film 24 alone or connecting holes to be formed therein with the metal plugs 42, 43 and 44 passing through the interlayer insulating film 24, the second cylinder interlayer insulating film 23b, the first cylinder interlayer insulating film 23a the silicon nitride film 32 and the interlayer insulation film 22 is/are formed, the connecting holes are filled with a third titanium nitride film and a tungsten film, and then the third titanium nitride film and the tungsten film out of the connecting holes are removed by a CMP method to form the metal plugs 42, 43 and 44 as show in FIG. 1.

Thereafter, a titanium film, an aluminum film and a titanium nitride film are sequentially formed as a laminated film by a sputtering method, and the laminated film is patterned using a lithography technique and a dry etching technique to form the second layer wires 61 and 61a (FIG. 1). Thereafter, the third layer wire and so on are formed, mounted on a package and bonding-wired to complete a DRAM).

The present invention is not limited to the above described mode but may be modified without departing from the spirit and scope of the present invention.

### (3) Evaluation on Characteristics of the Capacitor

### EXAMPLE 1

FIG. 13 is a schematic sectional view of a sample wafer prepared to evaluate capacitor characteristics of the semiconductor device according to the first mode of the present invention. The semiconductor device shown in FIG. 13 is manufactured as follows. First, the interlayer insulating film 22 is formed on the silicon substrate 10a doped with arsenic (As) of 4e20/cm³, and then the polysilicon plug 12 passing through the interlayer insulating film 22 is formed. Next, the silicon nitride film 32 is formed, the first cylinder interlayer insulating film 23a as an USG film having thickness of 1.5 μm is formed on the silicon nitride film 32 by a PECVD method using monosilane (SiH₄) and nitrogen monoxide (N₂O), and the second cylinder interlayer insulating film 23b as a PE-TEOS film having thickness of 1.5 μm is formed on the first cylinder interlayer insulating film 23a by a PECVD method using TEOS (Si(OC₂H₅)₄) and oxygen (O₂).

Next, the cylinder hole 96 passing through the first cylinder interlayer insulating film 23a, the second cylinder interlayer insulating film 23b and the silicon nitride film 32 is formed using a photolithography technique and a dry etching technique, and a surface of the polysilicon plug 12 is exposed to the bottom of the cylinder hole 96. Next, wet etching treatment (etching process) is carried out to enlarge the cylinder hole 96. The wet etching treatment by dipping the cylinder hole 96 into a mixture solution of ammonia (NH₃) and hydrogen peroxide (H₂O₂) with a ratio of 1:4 used as an etchant at 70° C. for one minute as shown in Table 1.

TABLE 1

For TEG of leak
current > 1e−16 A/cell
(number of measured TEG: 82)

| | | | Comparative | |
|---|---|---|---|---|
| Treatment time | Examples | | Examples | |
| 1 minute | 1 | 0% | 1 | 0% |
| 2 minutes | 2 | 0% | 2 | 12.2% |
| 4 minutes | 3 | 0% | 3 | 30.1% |
| 5 minutes | 4 | 0% | 4 | 60.1% |

(Wet etching: NH₃/H₂O₂ 70° C.)

Next, heat treatment is carried out at 700° C. for 10 minutes in a nitrogen atmosphere. Thereafter, the first titanium nitride film 51a (conductive film) having thickness of 15 nm as the lower electrode 51 is grown by a CVD method using titanium tetrachloride (TiCl₄) and ammonia (NH₃) as raw material gas and using a single wafer film forming apparatus with wafer temperature set to 600° C.

Next, a resist film is formed on the titanium nitride film 51a, the resist film is selectively removed to form a photoresist film 71 (protection resist film) having a predetermined shape, and the titanium nitride film 51a is selectively etched back using the photoresist film 71 to form the cup-shaped lower electrode 51. Thereafter, the photoresist film 71 is removed by a dry ashing method using vapor (H₂O), oxygen (O₂) and argon (Ar), and ashing residue is dissolved away by organic shipping liquid.

Thereafter, the aluminum oxide 52a (having thickness of 6 nm) as the capacitive insulating film 52 is formed on the surface of the lower electrode 51 by an ALD method using trimethyl aluminum ((CH₃)₃Al) and ozone (O₃) as raw material gas and using a batch type film forming apparatus with wafer temperature set to 350° C. Subsequently, the first titanium nitride film 53a (having thickness of 20 nm) as the upper electrode 53 is formed on the capacitive insulating film 52 by a CVD method using titanium tetrachloride and ammonia as raw material gas and using a single wafer film forming apparatus with wafer temperature set to 450° C. Thereafter, the second titanium nitride film 53a and the aluminum oxide film 52a are machined into the shape of upper electrode 53 by a photolithography technique and a dry etching technique to obtain the cylinder-shaped capacitor having height of 3 μm.

Next, the interlayer insulating film 24 as a silicon oxide film is formed, a connecting hole to be formed therein with the metal plug 44 passing through the interlayer insulating film 24 is formed, the connecting hole is filled with a third titanium nitride film and a tungsten film, and then the third titanium nitride film and the tungsten film out of the connecting hole is removed by a CMP method to form the metal plug 44.

Thereafter, a titanium film, an aluminum film and a titanium nitride film are sequentially formed as a laminated film by a sputtering method, the laminated film is patterned using a lithography technique and a dry etching technique to form the second layer wire 61, and a sample wafer of Example 1 shown in FIG. 13 is prepared.

### EXAMPLES 2 TO 4

In the wet etching treatment (etching process), as shown in Table 1, sample wafers of Examples 2 to 4 are prepared in a similar way as the sample wafer of Example 1 except for treatment time of 2 to 4 minutes.

### COMPARATIVE EXAMPLE 1

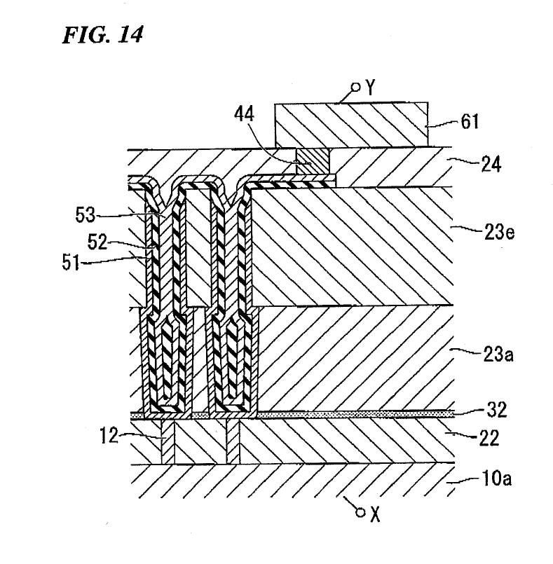

A sample wafer of Comparative Example 1 shown in FIG. 14 is prepared in a similar way as the sample wafer of Example 1 shown in FIG. 13 except that a BPSG (Boro-Phospho Silicate Glass) film 23d is used as the first cylinder interlayer insulating film and a PE-TEOS film 23e is used as the second cylinder interlayer insulating film

### COMPARATIVE EXAMPLES 2 TO 4

In the wet etching treatment (etching process), as shown in Table 1, sample wafers of Comparative Examples 2 to 4 are prepared in a similar way as the sample wafer of Comparative Example 1 except for treatment time of 2 to 4 minutes.

For 82 in-plane sites (TEG: Test Element Group) of the sample wafers of Examples 1 to 4 and Comparative Examples 1 to 4, each having 10 kilobit capacitors connected in parallel, a current value when a potential of silicon substrate 10a (terminal X) is set to 0V and a potential (Vpl) of the second layer wire 61 (terminal Y) is swept from 0 to ±10 V is measured to obtain data of I-V characteristics.

In addition, a percentage of the number of TEGs having leak current of more than 1×10⁻¹⁶ A/cell in the total number (82) of TEGs with an application voltage of ±1 V is obtained from the obtained I-V characteristics data, as shown in Table 1.

As shown in Examples 1 to 4 in Table 1, the sample wafers of the present invention show good results in that they has no TEG having leak current of more than 1×10⁻¹⁶ A/cell irrespective of wet etching treatment time taken to enlarge the cylinder hole 96.

On the contrary, as shown in Comparative Example 1 Comparative Example 4, the sample wafers of Comparative Examples have increased number of TEGs having leak current of more than 1×10⁻¹⁶ A/cell as wet etching treatment time taken to enlarge the cylinder hole 96 increases. It is believed that the reason for this is that, in the sample wafers of the Comparative Examples, there occurs a steep step at an interface between the BPSG film 23d and the PE-TEOS film 23e in the cylinder hole, and the step makes a portion at which ashing particles such as ions or radicals are difficult to arrive when the titanium nitride film of the lower electrode 51 is etched back and dry-ashed, thereby leaving alien substances in the cylinder holes 96.

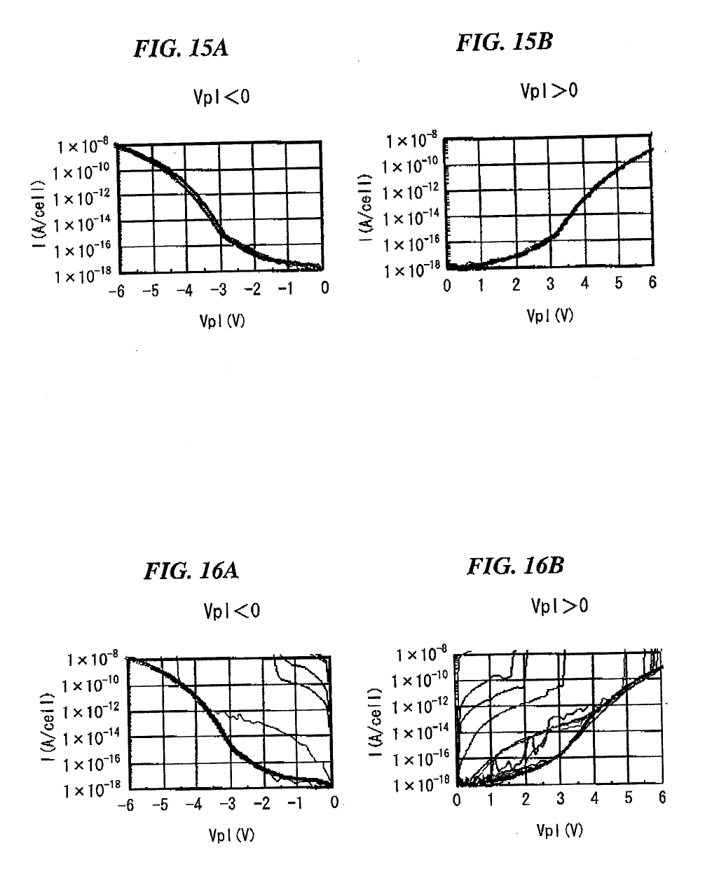

For 82 in-plane sites (TEG) of the sample wafers of Example 4 and Comparative Example 4, each having 10 kilobit capacitors connected in parallel, a current value when a potential of silicon substrate 10a (terminal X) is set to 0V and a potential (Vpl) of the second layer wire 61 (terminal Y) is swept from 0 to ±6 V is measured to obtain data of I-V characteristics as shown in FIGS. 15A to 16B.

FIGS. 15A and 15B are graphs showing I-V characteristics of the sample wafer of Comparative Example 4. FIG. 15A shows a current value when the potential (Vpl) is swept from 0 to −6 V. FIG. 15B shows a current value when the potential (Vpl) is swept from 0 to +6 V.

FIGS. 16A and 16B are graphs showing I-V characteristics of the sample wafer of Example 4, FIG. 16A shows a current value when the potential (Vpl) is swept from 0 to −6 V. FIG. 16B shows a current value when the potential (Vpl) is swept from 0 to +6 V.

As shown in FIGS. 15A and 15B, the sample wafer of Example 4 has small leak current for all TEGs in plane (leak current <1e-16A/cell, 1 V).

On the contrary, as shown in FIGS. 16A and 16B, the sample wafer of Comparative Example 4 has TEGs having large leak current in plane.

### EXPERIMENTAL EXAMPLES 1 TO 7

Sample wafers of Experimental Examples 1 to 7 are prepared in the same way as the sample wafer of Example 1 except for the first cylinder interlayer insulating film (lower layer), the second cylinder interlayer insulating film (upper layer), wet etchant to enlarge the cylinder hole 96, a ratio of etching rate of the first cylinder interlayer insulating film to etching rate of the second cylinder interlayer insulating film ((upper layer/lower layer) wet etching rate ratio), and treatment time of 4 minutes, as shown Table 2.

TABLE 2

| | | | | | For TEG having |
|---|---|---|---|---|---|
| | | | | | leak |
| | | | Wet etching | | current > 1e−16 A/cell |
| Kind of interlayer insulating film | | | | Wet | (number of |
| Experimental | | | | etching | measured TEGs; |
| Example | Upper layer | Lower layer | Etchant | rate ratio | 82) |
| 1 | PE-TEOS | BPSG | NH₃/H₂O₂ | 8.3 | 30.1% |
| 2 | PE-TEOS | BPSG | DHF | 1.2 | 0% |
| 3 | PE-TEOS | PSG | NH₃/H₂O₂ | 6.0 | 28.5% |
| 4 | PE-TEOS | PSG | DHF | 1.1 | 0% |
| 5 | PE-TEOS | USG | NH₃/H₂O₂ | 4.5 | 0% |
| 6 | PE-TEOS | USG | DHF | 2.6 | 0% |
| 7 | PE-TEOS | SOG | NH₃/H₂O₂ | 12.1 | 60.1% |

(Wet etching: 4 minutes)

For 82 in-plane sites (TEG) of the sample wafers of Experimental Example 1˜Experimental Example 7, each having 10 kilobit capacitors connected in parallel, a current value when a potential of silicon substrate 10a (terminal X) is set to 0V and a potential (Vpl) of the second layer wire 61 (terminal Y) is swept from 0 to 6 V is measured to obtain data of I-V characteristics.

In addition, a percentage of the number of TEGs having leak current of more than 1×10⁻¹⁶ A/cell in the total number (82) of TEGs is obtained from the obtained I-V characteristics data, as shown in Table 2.

As shown in Table 2, the sample wafers of the present invention (Experimental Examples 5 and 6) having the wet etching rate ratio of more than 2 and less than 6) have no TEG having leak current of more than 1×10⁻¹⁶ A/cell.

On the contrary, the sample wafers of Comparative Examples (Experimental Examples 1, 3 and 7) having the wet etching rate ratio of more than 6) have many TEGs having leak current of more than 1×10⁻¹⁶ A/cell. It is assumed that the reason for this is that a steep step occurs in the cylinder hole if the wet etching rate ratio is more than 6, thereby increasing leak current. Based on this assumption, if the wet etching rate ratio is less than 6, since to steep step occurs in the cylinder hole and accordingly the inner wall of the cylinder hole becomes smooth, it is believed that no alien substance is left in the cylinder hole when a resist film formed in a lower electrode forming process is dry-ashed, thereby preventing leak current from increasing.

In the sample wafers of Comparative Examples (Experimental Examples 2 and 4) having the wet etching rate ratio of less than 2, since a difference between the hole diameter of the first cylinder hole 50a and the hole diameter of the second cylinder hole 50b can not be sufficiently obtained, charge storage capacitance in the first cylinder hole 50a is insufficient. Based on this fact, it can be seen that the wet etching rate ratio is preferably set to more than 2 to enlarge the cylinder hole and accordingly increase the charge storage capacitance.

While preferred embodiments of the present invention have been described and illustrated above, it should be understood that these are exemplary of the present invention and are not to be considered as limiting. Additions, omissions, substitutions, and other modifications can be made without departing from the spirit or scope of the present invention. Accordingly, the present invention is not to be considered as being limited by the foregoing description, and is only limited by the scope of the appended claims.

The present invention is applicable to DRAMs, hybrid LSIs including DRAMs, etc.

What is claimed is:

1. A semiconductor device comprising:
a first cylinder interlayer insulating film;
a second cylinder interlayer insulating film formed on the first cylinder interlayer insulating film;
a cylinder hole including a first cylinder hole formed in the first cylinder interlayer insulating film and a second cylinder hole formed in the second cylinder interlayer insulating film and communicating with the first cylinder hole; and
a capacitor including a lower electrode formed to cover bottom and lateral sides of the cylinder hole and an upper electrode formed on a surface of the lower electrode via a capacitive insulating film,
wherein the first cylinder interlayer insulating film has an etching rate for etchant used for wet-etching of the first cylinder interlayer insulating film and the second cylinder interlayer insulating film, which is two to six times as high as an etching rate for the second cylinder interlayer insulating film;
a hole diameter of the first cylinder hole is larger than a hole diameter of the second cylinder hole; and
the hole diameter of the second cylinder hole near an interface between the first cylinder interlayer insulating film and the second cylinder interlayer insulating film increases as the second cylinder hole approaches the interface.

2. The semiconductor device according to claim 1, wherein the fast cylinder interlayer insulating film is formed of an USG film.

3. The semiconductor device according to claim 1, wherein the second cylinder interlayer insulating film is formed of a PE-TEOS film.

4. The semiconductor device according to claim 1, wherein the etchant is a mixture solution of NH₃ and H₂O₂.

5. The semiconductor device according to claim 1, wherein the lower electrode is formed of a titanium nitride film.

6. The semiconductor device according to claim 1, wherein the capacitive insulating film is one of an aluminum oxide film, a hafnium oxide film, a zirconium oxide film and a tantalum oxide film, or a laminate of at least two of the films.

7. The semiconductor device according to claim 1, wherein the lower electrode is electrically connected to MISFET for memory cell selection provided in bottom of the capacitor.

8. The semiconductor device according to claim 1, wherein an angle θ between the interface and an extension direction of an inner wall of the second cylinder hole contacting the interface falls within a range of 60° to 85°.

9. A method of manufacturing a semiconductor device having a capacitor including a lower electrode formed to cover bottom and lateral sides of a cylinder hole and an upper electrode formed on a surface of the lower electrode via a capacitive insulating film, a process of forming the capacitor comprising the steps of:
sequentially forming a first cylinder interlayer insulating film and a second cylinder interlayer insulating film;
forming the cylinder hole including a first cylinder hole formed in the first cylinder interlayer insulating film and a second cylinder hole formed in the second cylinder interlayer insulating film and communicating with the first cylinder hole;
wet etching the cylinder hole using etchant allowing an etching rate of the first cylinder interlayer insulating film to be two to six times as high as an etching rate of the second cylinder interlayer insulating film such that a hole diameter of the first cylinder hole is larger than a hole diameter of the second cylinder hole and the hole diameter of the second cylinder hole near an interface between the first cylinder interlayer insulating film and the second cylinder interlayer insulating film increases as the second cylinder hole approaches the interface;
forming the lower electrode on the bottom and lateral sides of the cylinder hole; and
forming the upper electrode on the surface of the lower electrode via the capacitive insulating film.

10. The method of manufacturing a semiconductor device, according to claim 9, wherein the first cylinder interlayer insulating film is formed of an USG film.

11. The method of manufacturing a semiconductor device, according to claim 9, wherein the second cylinder interlayer insulating film is formed of a PE-TEOS film.

12. The method of manufacturing a semiconductor device, according to claim 9, wherein the etchant is a mixture solution of NH₃ and H₂O₂.

13. The method of manufacturing a semiconductor device, according to claim 9, wherein the lower electrode is formed of a titanium nitride film.

14. The method of manufacturing a semiconductor device, according to claim 9, wherein the capacitive insulating film is one of an aluminum oxide film, a hafnium oxide film, a zirconium oxide film and a tantalum oxide film, or a laminate of at least two of the films.

15. The method of manufacturing a semiconductor device, according to claim 9, wherein the step of forming the lower electrode includes:
forming a conductive film to be the lower electrode;
forming a resist film on the conductive film and forming a protection resist film having a predetermined shape by selectively removing the resist film;
forming the lower electrode by selectively removing the conductive film using the protection resist film; and
removing the protection resist film using a dry ashing method.
